(19) United States
(12) Patent Application Publication
(10) Pub. No.: US 2004/0087080 A1
(43) Pub. Date: May 6, 2004

(54) Methods for producing thin layers, such as for use in integrated circuits

(76) Inventors: Uwe Wellhausen, Yokohama-shi (JP); Rainer Bruchhaus, Yokohama-shi (JP); Nicolas Nagel, Yokohama-shi (JP); Stefan Gernhardt, Yokohama-shi (JP)

Correspondence Address: FISH & RICHARDSON, PC, 12390 EL CAMINO REAL, SAN DIEGO, CA, 92130-2081, US

(21) Appl. No.: 10/279,743

(22) Filed: Oct. 23, 2002

(51) Int. Cl. H01L 21/31; H01L 21/8242; H01L 21/8234; H01L 21/8244; H01L 21/469

(52) U.S. Cl. 438/238; 438/240

(57) ABSTRACT

An layer for a structure such as a ferro-capacitor is formed by a three stage process consisting of (i) applying a wetting layer 23 over some or all of the structure 21, (ii) applying a second layer 25 of a second material over the wetting layer 23, and (iii) transforming the second material by a chemical reaction. In an example, the second material is Al, and step (iii) inclues oxidising the Al layer 25 to form an Al₂O₃ layer 27. The wetting layer 21 is preferably applied by a process having good step coverage even in high aspect regions of the substrate, even though that process may have a low deposition rate. The wetting layer 21 is preferably formed of a material over which the second material has a high mobility, so that the aluminium layer—and the subsequent Al₂O₃ layer—are relatively uniform in thickness. Step (iii) may be preceded by a step of enhancing lateral mobility of the second material, e.g. by a heat treatment.

### FIELD OF THE INVENTION

The present invention relates to techniques for producing an layer with very high conformality in a device such as an integrated circuit, and to devices incorporating a layer formed by the method.

### BACKGROUND OF THE INVENTION

The are many situations in the design of integrated circuits in which it is desirable to produce a layer of material. For example, it is known to provide a layer of aluminium oxide Al₂O₃ in an integrated circuit, e.g. as a layer which blocks the unwanted diffusion of compounds, e.g. byproducts such as hydrogen formed during the “backend processing” of semiconductor devices including ferro-capacitors. The Al₂O₃ Is conventionally applied by direct sputtering using an Al₂O₃ target. However, a drawback of such techniques is that it is difficult to generate barrier layers of uniform thickness in regions of the integrated circuit which have are steep (i.e. have high aspect ratios).

This problem is illustrated in FIG. 1 which shows schematically a cross-section of a portion of an integrated circuit having at least a ferrocapacitor (and typically many other components) formed on the surface of a wafer (not shown) extending generally in the horizontal direction in FIG. 1. The ferrocapacitor includes a layer of ferroelectric material 1 sandwiched between two conductive layers 3, 5. The layer 3 is contacted by contact 7. Portions 9, 13 of the structure are formed of SiO₂ and two layers 16, 17 of Al₂O₃ are provided as blocking layers. The thickness of the layers 16, 17 is severely reduced in the portions 15 where the surface which it covers has greatest steepness relative to the plane of the wafer, so in such regions the blocking is least successsfull. The relatively thin portions 15 are unfortunately located in regions which are critical for the operation of the ferrocapacitor, and there is a risk of providing a diffusion path for H₂ to the capacitor.

One way of ensuring that the thickness of layers 16, 17 is adequate in all regions is simply to make the layers 16, 17 thicker over the whole surface. However, forming a thick layer 16, 17 has disadvantages because it can cause unwanted side-effects to subsequent processes in the fabrication of the integrated circuit. For example, there may be a difficulty in performing reactive ion etching (RIE) during etching of contact holes for the contacts 7.

### SUMMARY OF THE INVENTION

The present invention seeks to address the problems above, and in particular to provide new and useful methods for producing an Al₂O₃ layer in a device such as an integrated circuit.

In general terms the invention proposes that the Al₂O₃ layer is formed by a three stage process consisting of (I) applying a first layer of first material over at least part of a structure (which may be a substrate or components formed on a substrate of an integrated circuit), (ii) applying a second layer of a second material over the first layer, and (iii) modifying the second material.

The first layer is here referred to as a “wetting” layer, because it enhances lateral mobility of a material deposited over it, in analogy to a layer which promotes the mobility of water on a hydrophobic surface. Thus, the application of the second layer need not be a method which results in high step coverage, e.g. it may be a lower cost method. The lateral mobility effect induced by the wetting layer is what principally determines the step coverage of the second material, rather than how the second layer is applied. For this reason, the wetting layer is preferably applied by a process having good step coverage even in steep regions of the substrate, such as a deposition process with high collimation. Collimation is a sputtering process in which the arrival of material is at an angle normal to the wafer surface. The material may be collimated by a thick honeycomb grid that blocks off-angle metal atoms or by ionizing the metal atoms and attracting them towards the wafer.

Optionally, step (iii) may be preceded by a step during which the lateral mobility of the second material is enhanced, e.g. by increased temperature, exposure to photons, etc.

The wetting layer may be formed by a process which has a relatively low deposition rate (for example, in the present invention the wetting layer may be formed to be no thicker than about 100 A (10 nm); preferably it is about 50 A (5 nm) thick), yet the wetting layer is preferably formed as a relatively uniform layer over the substrate. The wetting layer is preferably chosen to be a material upon which the second material has a high surface migration rate.

In a particular example of the invention, the second material is Al, and step (iii) is the oxidation of the Al to form Al₂O₃. In this case, the wetting layer is preferably chosen to be a material upon which Al has a high surface migration rate, such as Ti or Nb or a combination of the two.

The Al layer is preferably formed by sputtering. Due to the high lateral mobility of the Al over the wetting layer, the Al layer can be formed relatively uniformly. It may have a thickness in the range 100 to 300 A (10 to 30 nm), or more preferably about 200 A (20 nm).

The oxidation step is preferably performed at an elevated temperature, such as about 450 degrees centigrade.

### BRIEF DESCRIPTION OF THE FIGURES

A method which is an embodiment of the invention will now be described in detail for the sake of illustration only with reference to the following drawings in which:

FIG. 1 shows the construction of a known ferrocapacitor structure;

FIG. 2 shows the deposition of a wetting layer in a first step of the embodiment;

FIG. 3 shows the deposition of an Al layer over the wetting layer in a second step of the embodiment; and

FIG. 4 shows the oxidation of the Al layer in a third step of the embodiment.

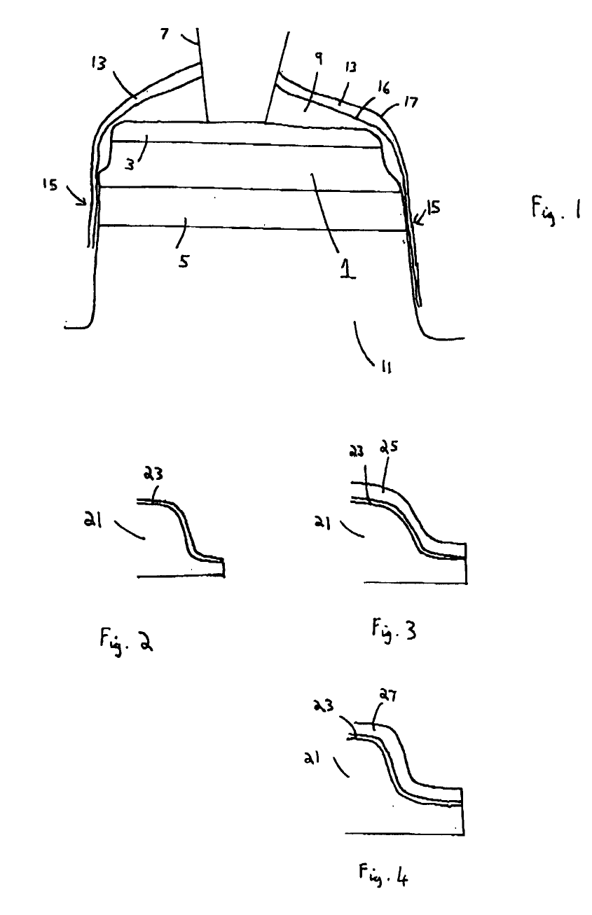

### DETAILED DESCRIPTION OF THE EMBODIMENTS

FIG. 2 shows a structure 21 (e.g. a substrate optionally having components such as ferrocapacitors formed thereon) on at least part of which an Al₂O₃ layer is to be formed.

In a first step step of the embodiment, as shown in FIG. 2, an underlayer 23 (“wetting layer”) of a material such as Ti or Nb is formed having a uniform thickness over substantially the whole of the substrate 21 of about 5 nm. This deposition may be performed by sputtering, MOCVD (metalorganic chemical vapour deposition) or ALD (atomic layer deposition). In particular, it can be performed by collimation, since although collimation typically reduces the deposition rate the thickness of the underlayer 23 need not be high. Although the use of Ti or Nb is preferable, other materials may be used instead, preferably materials over which Al has a high surface mobility.

In a second step of the embodiment, as shown in FIG. 3, a layer 25 of Al (or more generally comprising a component of metallic Al) is deposited over the underlayer 23. This deposition may be performed by sputtering, or by MOCVD, LPCVD or Plasma CVD. Since the wetting layer 23 has a high surface mobility, the Al layer 25 has a substantially uniform thickness of about 20 nm even over steep regions of the structure. The deposition is preferably at a higher rate than that of the deposition used to form the underlayer 23.

In a third step of the embodiment, the Al layer 25 is oxidised by exposing it at a high temperature such as 450 degrees centigrade to an atmosphere containing oxygen to convert it into a layer 27 of Al₂O₃ having low mobility over the underlayer 23 and structure 21. Typically, the underlayer will survive this treatment.

Although only a single embodiment of the invention has been described, many variations are possible within the scope of the invention as will be clear to a skilled reader.

1. A method of forming a layer over at least part of a structure, the method comprising the steps of, in order
(i) forming an underlayer of a first material over at least part of the structure;
(ii) forming a second layer of a second material over the underlayer, and
(iii) modifying the first and/or second material by a chemical reaction.

2. A method according to claim 1 further including a step, preceding step (iii), of promoting the lateral mobility of the second material over the first material.

3. A method according to claim 1 in which the second material comprises Al, and step (iii) includes oxidising the Al layer to form an Al₂O₃ layer.

4. A method according to claim 1 in which the underlayer is formed by a highly conformal layer deposition process, such as atomic layer deposition or collimated sputtering.

5. A method according to claim 1 in which the first material comprises at least one of Ti and Nb.

6. A method according to claim 1 in which the second material is deposited at a higher deposition rate than the first material.

7. An integrated circuit comprising a layer formed by a method according to claim 1.

8. An integrated circuit comprising a layer of Al₂O₃ formed by a method according to claim 3.

9. An integrated circuit according to claim 8 in which the Al₂O₃ layer overlies at least part of a ferroelectric capacitor.
